(19) United States
(12) Patent Application Publication
(10) Pub. No.: US 2003/0182611 A1
(43) Pub. Date: Sep. 25, 2003

(54) METHOD FOR VERIFYING ERROR CORRECTION CODE FUNCTION OF A COMPUTER SYSTEM

(76) Inventor: Chung-Che Wu, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/248,048

(22) Filed: Dec. 13, 2002

(30) Foreign Application Priority Data
Mar. 19, 2002 (TW) 091105240

(51) Int. Cl. H03M 13/00

(52) U.S. Cl. 714/752

(57) ABSTRACT

A method for verifying error correction code (ECC) function of a computer system is provided. The method includes of enabling the ECC function and writing first test data into the ECC memory. Further, the ECC module will store verifying data according to the first test data. Second, disable the ECC function and overwrite the first test data with second test data. Finally, enable the ECC function to try to recover the first test data by using the second test data and the verifying data.

### BACKGROUND OF INVENTION

1. Field of the Invention

The present invention relates in general to an evaluation method for verifying error correction code function of a computer system, and more particularly, to a software evaluation method which avoids unwanted damage of a memory module and has a flexible verifying process to completely evaluate the error correction code function of the computer system.

2. Description of the Prior Art

Over the past few years, both desktop and laptop computers have rapidly increased in computing power, and have rapidly increased in local storage capacity due to demand by sophisticated operating systems and application software. Traditionally, storage devices mainly fall into two catagories: random access memory (RAM) and read only memory (ROM). The read only memory is utilized to store unchanged data, such as the basic input/output system (BIOS) of the computer, and the random access memory is utilized to write and read data to and from any memory address by the users.

In addition to the hard disk drive, the random access memory is the major storage device of the computer. Because of the rapid data access of the random access memory, the reading and writing processes of the processor go through the random access memory. A major random access memory of the computer system is dynamic random access memory (DRAM), and the dynamic random access memory requires constantly refreshing the stored data to ensure correct storage. However, due to the higher operating speed of the processor, the speed of the conventional dynamic random access memory cannot catch up with the speed of higher operation clocks, which has gone up to the scale of gigahertz. In order to solve the speed problem, advanced dynamic random access memory, such as a synchronous dynamic random access memory (SDRAM), is developed to achieve a higher memory bandwidth and improve the performance of the computer. Nevertheless, the high speed computer system is generally has the side effects of high frequency operation such as electromagnetic interference and other related undesirable effects. The electromagnetic interference is the major cause for error data transmission and will lower the stability of the computer system.

In order to reduce the effect of error data transmission on the operation of computer systems, a variety of error detection or correction methods have been developed and are widely applied to the related digital systems. Therefore, when binary data is transmitted or stored, at least one extra bit is frequently added for the purpose of error detection. In general, the more extra bits there are means the more powerful the error detection method is. Among various kinds of error detection methods, the most straightforward approach is the parity-bit check. Take the parity-bit check for instance, if data is being transmitted in groups of 7 bits, an extra bit can be added to each group of 7 bits such that the total number of ones in each block of 8 bits is odd. When the total number of ones in the block is odd, the extra bit is called odd parity bit. Alternatively, the parity bit could be chosen such that the total number of ones in the block is even, in which case the extra bit is called even parity bit. Take odd parity for example, if any single bit in the 8-bit word is changed from 0 to 1 or from 1 to 0, the parity is no longer odd. Therefore, if any single bit error occurs in transmission of a word with odd parity, the presence of this error can be detected because the number of ones in the word has been changed from odd to even. However, if any two-bit error occurs in transmission of a word with odd parity, the presence of this error cannot be detected because the number of ones in the word is still odd. Besides, the parity-bit check is capable of error detecting only and is not capable of error correcting. Thereby, advanced methods of error correction code function of digital systems are required to detect bit error as well as to correct error bits.

A schematic diagram of a computer system 10 having error correction code function is shown in FIG. 1. The computer system 10 comprises a processor 12 to control the operation of digital data in the computer system 10, a memory 14 to store the data of computer system 10, and a control chip 16, such as a bridge, to manage the data transmission between the processor 12 and the memory 14. The memory 14 further comprises a memory unit 20 and a data error correction unit 22, and the control chip 16 comprises an error correction module 18. The memory 20 is employed to store the data of the computer system 10, and the data error correction unit 22 stores the corresponding verifying data. The control chip 16 receives the transmitted data from the processor 12 and stores the data into the memory unit 20 of the memory 14. At the same time, the error correction code module 18 generates a corresponding verifying data according to the transmitted data and stores the verifying data into the data error correction unit 22. Take hamming code for example, the feature of single-error-correcting and double-error-detecting hamming code (SEC-DED) is especially fit for the memory-related data processing. Before each operation data having 64 bits is stored into the memory unit 20, the verifying data having 8 bits is generated by the error correction code module 18. Every time when the processor 12 is going to fetch the stored operation data in the memory unit 20 of the memory 14, the memory 14 releases both the stored operation data in memory unit 20 and the corresponding verifying data in the data error correction unit 22 for the error correction code module 18. Based on the operation data and the verifying data, some syndrome bits are generated. The data transmission of the operation data is correct if each bit of the syndrome bits is 0. Nevertheless, if any one bit of the syndrome bits is equal to 1, the error bit can be found and corrected with the aid of the verifying data. If any two bits of the syndrome bits are equal to 1, the bit errors can be detected without correction due to the feature of the hamming code system described above. Consequently, in order to achieve desirable functions of error correction for the computer system 10, the computer system 10 must be equipped with the error correction code module 18 to process the verifying data, and the memory 14 must include a data error correction unit 14 to save the verifying data. And in order to evaluate the error correction code function of the computer system 10, an intentional error bit of the operation data is required to test the performance of the error correction code module 18 and the data error correction unit 22.

Referring to FIGS. 1 and 2, FIG. 2 shows a schematic printed circuit board (PCB) of the memory 14 in FIG. 1. Customarily, it is easy for the users and/or developers of the computer system 10 to expand the memory module, such as a single inline memory module (SIMM) or a dual inline memory module (DIMM), to improve the performance of the computer system 10. The single inline memory module comprises a 32-bit gold finger and the dual inline memory module comprises a 64-bit gold finger, and both can be utilized to expand the memory capacity. As aforementioned, the memory 14 in FIG. 1 is actually the same as the memory module 23 in FIG. 2, and the memory module 23 is a printed circuit board with a plurality of memory chips 24 to form the memory unit 20 and the data error correction unit 22. The memory unit 20 is utilized to store the operation data and the data error correction unit 22 is utilized to store the verifying data. Furthermore, the memory module 23 comprises a gold finger 26 with a plurality of connecting pins for the memory chipsets 24 to interface with the computer system 10 and the memory module 23. Therefore, as described above, it is very easy for the users to expand the memory capacity by just plugging the gold finger 26 of the memory module 23 into the corresponding memory slot. However, if bad contact occurs between the memory slot and the gold finger 26 of the memory module 23, the data transmission related to the memory unit 20 is not done correctly and incorrect data may be stored in the memory unit 20. Therefore, it is extremely important to evaluate the error correction code function of the computer system 10. To do so, an intentional bad contact, such as an artificial hardware rework, between the gold finger 26 and the memory slot is required. While transmitting a test data A to the memory unit 20 of the memory 14, the error correction code module 18 generates a verifying data B to be stored in the data error correction unit 22. Because of the intentional bad contact of the gold finger 26, the test data stored in the memory module 23 is now A instead of the original test data A. If the error correction code function of the computer system 10 functions accurately, the incorrect test data A can be corrected by the error correction code module 18 with the aid of the verifying data B, and a correct original data A is recovered. In other words, even though bad contact occurs to the gold finger 26, the memory-related data transmission is still functioning correctly. Conversely, if the error correction code function of the computer system 10 fails, the incorrect test data A cannot be recovered to the original data A, and the memory-related data transmission also fails.

As is well known, the artificial hardware rework of the memory module 23 depends on the skills of the operators and is not quite reliable for a precision evaluation. In addition, the hardware destructive method requires lots of man-hours, and unwanted damage of the memory module 23 may occur. Furthermore, the evaluation is based on the rework pin only, and other tests related to other pins are not available.

### SUMMARY OF INVENTION

It is therefore a primary objective of the claimed invention to provide a hardware nondestructive and cost-effective method to evaluate the error correction code function of the computer system completely to solve the prior art problems.

According to the claimed invention, a method for verifying error correction code (ECC) function of a computer system is provided. The computer system comprises a processor for controlling the computer system, a storage device for storing data of the computer system, and an error correction code (ECC) module for executing the ECC function of the computer system. The method comprises the following consecutive steps: (a) after enabling the ECC module, using the processor to write a first test data into the storage device, and using the ECC module to generate a verifying data according to the first test data and store the verifying data in the storage device, (b) disabling the ECC module, and using the processor to overwrite the first test data stored in the storage device with second test data which is different from the first test data, (c) enabling the ECC module, and using the ECC module to generate a third test data according to the second test data and the verifying data, and (d) comparing the first test data and the third test data to verify the ECC function of the computer system.

It is a major advantage of the claimed invention that the method for evaluation of the data correction function of the computer system is based on a hardwarenondestructive and cost-effective process, which avoids the unwanted damage of the memory module and has a flexible verifying process to evaluate the error correction code function of the computer system completely.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 shows a schematic diagram of a computer system having error correction code function according to the prior art.

FIG. 2 shows a schematic printed circuit board of a memory in FIG. 1.

FIG. 3 is a flow chart diagram of an evaluation method for verifying error correction code function of the computer system according to the preferred embodiment of the present invention.

FIGS. 4 to 6 give detailed signal-processing diagrams of the related processes of the evaluation method for verifying error correction code function of the computer system according to the preferred embodiment of the present invention.

### DETAILED DESCRIPTION

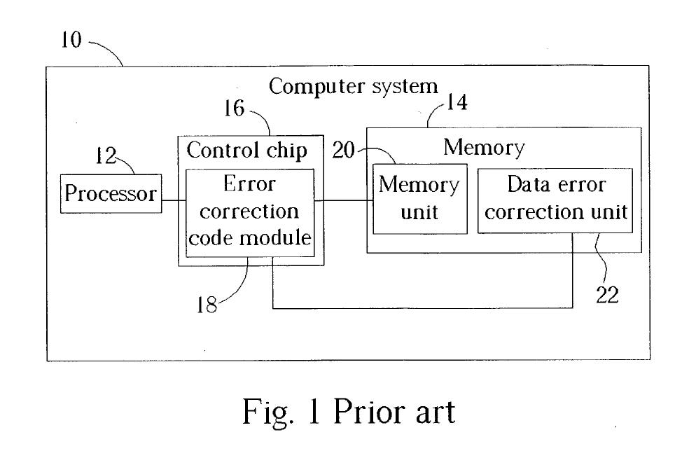

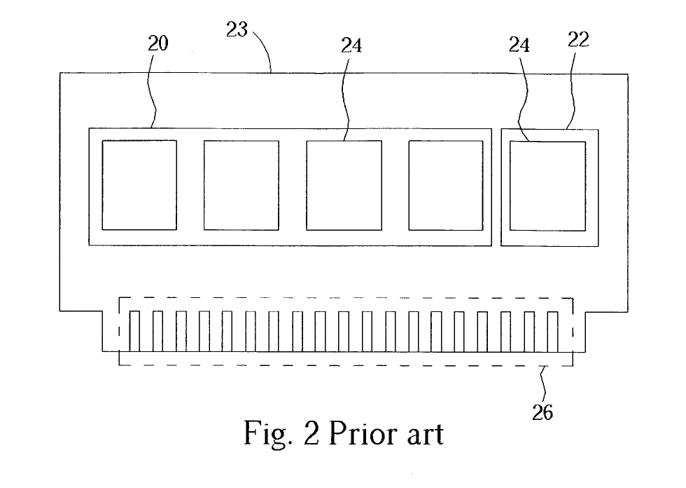

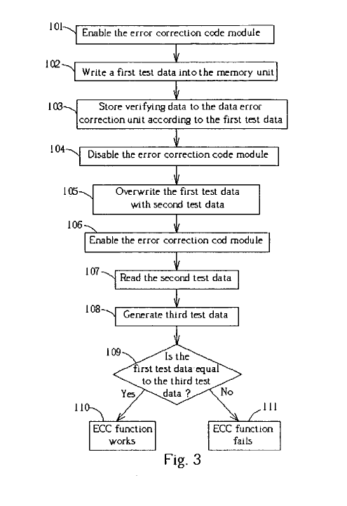

Please refer to FIGS. 1 and 3. FIG. 3 gives a flow chart diagram of the evaluation method for verifying error correction code function of the computer system 10 according to a preferred embodiment of the present invention. The evaluation method in FIG. 3 comprises the following consecutive steps:

Step 101 enable the error correction code module 18;

Step 102:

write a first test data into the memory unit 20 with a first memory address by processor 12;

Step 103:

store a verifying data to the data error correction unit 22 according to the first test data by the error correction code module 18;

Step 104: disable the error correction code module 18;

Step 105:

overwrite the first test data with a second test data in the memory unit 20 with the first memory address by the processor 12;

Step 106: enable the error correction code module 18;

Step 107:

read the second test data from the memory unit 20 with the first memory address by the processor 12;

Step 108:

generate a third test data according to the verifying data and the second test data by the error correction code module 18;

Step 109:

compare the first test data with the third test data, if equal go to step 110, if different go to step 111;

Step 110: the error correction code function of the computer system works;

Step 111: the error correction code function of the computer system fails;

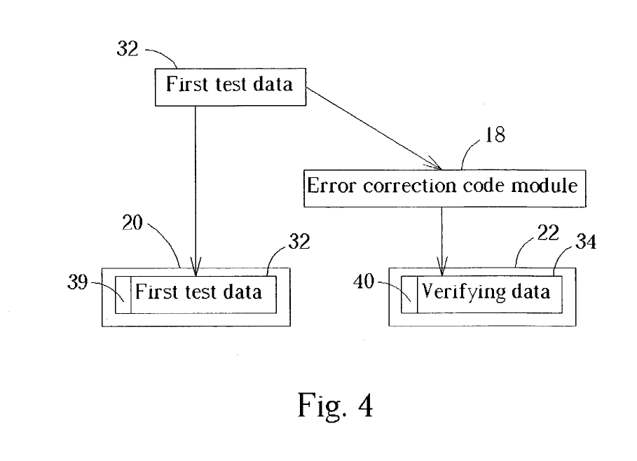

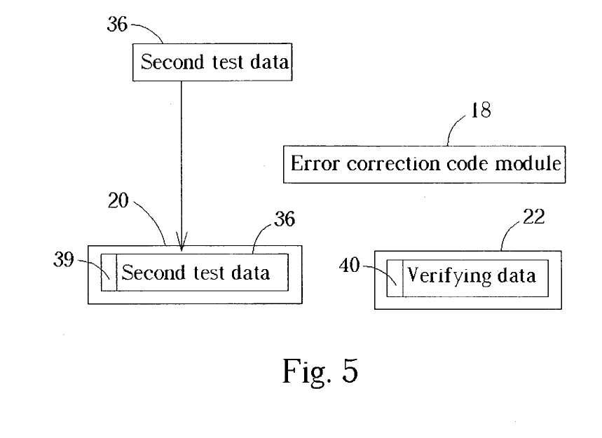

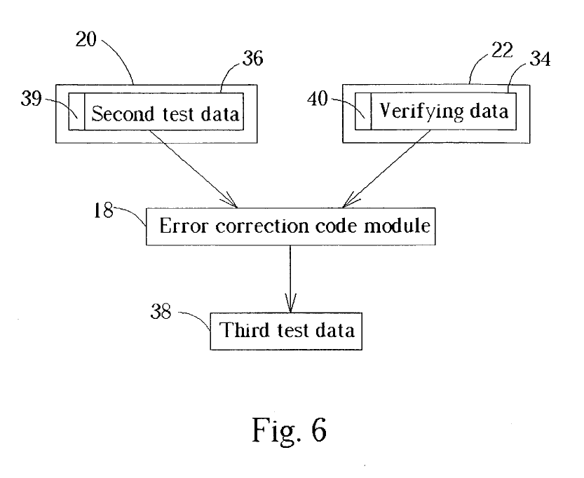

Referring to FIGS. 1, 4, 5, and 6, FIGS. 4 to 6 are detailed signal-processing diagrams of the related processes of the error correction code function according to one preferred embodiment of the present invention. The preferred embodiment is applied to the computer system 10 with the prior art error correction code module 18 as shown in FIG. 1. First of all, the error correction code module 18 is enabled to enable the error correction function of the computer system 10. Subsequently, the processor 12 outputs a first test data 32 and stores the first data 32 in the memory unit 20 of the memory 14 with memory address 39. At the same time, the error correction code module 18 generates a corresponding verifying data 34 based on the first test data 32 and stores the verifying data 34 in the data error correction unit 22 of the memory 14 with memory address 40 as shown in FIG. 4. Thereafter, the error correction module 18 is disabled to disable the error correction function of the computer system 10. Afterward, the processor 12 outputs a second test data 36 having the same bit-length of the first test data 32 to overwrite the first test data 32 in the memory unit 20. The second test data 36 differs from the first test data 32 for at most one bit. As shown in FIG. 5, since the error correction function of the computer system 10 is now disabled, the verifying data 34 in the data error correction unit 22 with memory address 40 is held unchanged while the second test data 36 is overwriting the first test data 32. Next, the error correction code module 18 is enabled again to enable the error correction function of the computer system 10. Then, the processor 12 reads the second test data 36 in the memory unit 20 with memory address 40. Because the error correction code module 18 is now enabled and the verifying data 34 is unchanged while saving the second test data 34, the error correction code module 18 will now process the second test data 36 with the verifying data 34 corresponding to the first test data 32 and generate a third test data 38 as shown in FIG. 6. If the error correction code function of the computer system 10 functions properly, the error correction code module 18 is able to recover the first test data 32 from the second test data 36 with the aid of the verifying data 34 corresponding to the first test data 32. That is to say, if the third test data 38 equals the first test data 32, the error correction code function of the computer system 10 works. Conversely, if the third test data 38 differs from the first test data 32, the error correction code function of the computer system 10 fails. Normally, the breakdown of the error correction code function of the computer system 10 comes from the malfunction of the error correction code module 18 or the memory 14.

In the preferred embodiment, even though both the first test data 32 and the second test data 36 are composed of a plurality of data bits and the second test data 36 differs from the first test data 32 by at most one bit, which is especially fit for the data error correction method of the hamming code system as is described before, the test conditions can be adjusted and applied to other data error correction systems.

Compared to the prior art evaluation method, the evaluation method of the present invention takes advantage of software control technique to achieve a hardware nondestructive and cost-effective method for verifying the error correction function of the computer system. In summary, the evaluation method of the present invention comprises the following consecutive processes. After the ECC module is enabled, the processor writes a first test data into the storage device, and the ECC module generates a verifying data according to the first test data and stores the verifying data in the storage device. Then the ECC module is disabled, and the processor overwrites the first test data stored in the storage device with a second test data, which is different from the first test data. Again, the ECC module is enabled, and the ECC module generates a third test data according to the second test data and the verifying data. Finally, the ECC function of the computer system is verified by the result of comparison between the first test data and the third test data. Since the evaluation method of the present invention is based on the software control process, the flexible programming can be easily designed to test any memory address bit of the computer system for a complete evaluation. As a result, the evaluation method of the present invention avoids the hardware destructive process and saves lots of man-hours required for the artificial hardware rework. It is also certain that the evaluation method can be applied to any system with data error correction function, such as a hard disk drive having data error correction function.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for verifying error correction code (ECC) function of a computer system, said computer system comprising a processor for controlling said computer system; a storage device for storing data of said computer system; and an error correction code (ECC) module for executing said ECC function of said computer system; said method comprising steps of:
after enabling said ECC module, said processor written first test data into said storage device, and said ECC module generated verifying data according to a first test data and store said verifying data in said storage device;
disabling said ECC module, and said processor overwritten said first test data stored in said storage device with a second test data which is different from said first test data;
enabling said ECC module, and said ECC module generated a third test data according to said second test data and said verifying data; and
comparing said first test data and said third test data to verify said ECC function of said computer system.

2. The method of claim 1 wherein said computer system further comprises a control chip electrically connected to the processor and the storage device for controlling data transmission between the processor and the storage device.

3. The method of claim 2 wherein said ECC module is disposed in said control chip.

4. The method of claim 1 wherein said first test data and said second test data have said same number of bits.

5. The method of claim 1 wherein if said first test data is different from said third test data, then said ECC function of said computer system is not able to be performed correctly.

6. The method of claim 1 wherein said first test data and said second test data each have a plurality of bytes, and said first test data and said second test data differ in no more than 1 bit per byte.

7. The method of claim 1 wherein said storage device is a hard disk drive.

8. The method of claim 1 wherein said storage device is a memory set.

9. The method of claim 8 wherein said memory set is a dynamic random access memory (DRAM).

10. A method for verifying error correction code (ECC) function of a computer system, said computer system comprising a storage device for storing a plurality of data and a plurality of corresponding verifying data; and an error correction code (ECC) module for generating corresponding verifying data for each data; said method comprising:
enabling said ECC module, and writing a first test data into said storage device;
disabling said ECC module, and overwriting said first test data stored in said storage device with a second test data, which is different from said first test data;
enabling said ECC module; and
reading said second test data and checking,wherein if said second test data has been corrected to become said first test data to verify said ECC function of said computer system.

11. The method of claim 10 wherein said computer system further comprises a control chip electrically connected to a processor and said storage device for controlling data transmission between said processor and said storage device.

12. The method of claim 11 wherein said ECC module is disposed in said control chip.

13. The method of claim 10 wherein said first test data and said second test data have said same number of bits.

14. The method of claim 10 wherein if said second test data read from said storage device is different from said first test data, then said ECC function of said computer system is not able to be performed correctly.

15. The method of claim 10 wherein said first test data and said second test data each have a plurality of bytes, and said first test data and said second test data differ in no more than 1 bit per byte.

16. The method of claim 10 wherein said storage device is a hard disk drive.

17. The method of claim 10 wherein said storage device is a memory set.

18. The method of claim 17 wherein said memory is a dynamic random access memory (DRAM).
